(19) United States
(12) Patent Application Publication
(10) Pub. No.: US 2018/0097154 A1
(43) Pub. Date: Apr. 5, 2018

(54) LED EMITTER AND METHOD FOR MANUFACTURING THE SAME

(71) Applicant: OSRAM Opto Semiconductors GmbH, Regensburg (DE)

(72) Inventors: Jan Marfeld, Regensburg (DE); Christian Betthausen, Regensburg (DE); Thomas Schlereth, Regensburg (DE); Ivar Tangring, Regensburg (DE)

(21) Appl. No.: 15/719,649

(22) Filed: Sep. 29, 2017

(30) Foreign Application Priority Data
Sep. 29, 2016 (DE) 10 2016 218 827.5

(51) Int. Cl. H01L 33/50; H01L 27/15

(52) U.S. Cl. CPC H01L 33/505; H01L 2933/0041; H01L 33/504; H01L 27/153

(57) ABSTRACT

In various embodiments, a light emitting component is provided. The light emitting component includes a plurality of light emitting semiconductor chips. The semiconductor chips are arranged on at least one carrier. The semiconductor chips are electrically contacted. The light emitting component further includes a converter. The converter is configured to convert light in a first wavelength range, said light being emitted by at least one portion of the light emitting semiconductor chips, at least partly into light in a second wavelength range. The converter is formed separately from the at least one carrier.

### CROSS-REFERENCE TO RELATED APPLICATION

This application claims priority to German Patent Application Serial No. 10 2016 218 827.5, which was filed Sep. 29, 2016, and is incorporated herein by reference in its entirety.

### TECHNICAL FIELD

Various embodiments relate generally to a light emitting component, e.g. a light emitting semiconductor chip component, and also a method for manufacturing such a light emitting component.

### BACKGROUND

Light emitting semiconductor chips, also called light emitting diodes or LEDs for short, constitute a light source having a good efficiency since they convert a large proportion of the required electric current into light. In recent years, illuminants including such light emitting semiconductor chips have been developed which have a similar appearance to conventional incandescent lamps and can also be used in the same way as conventional incandescent lamps. In this case, linear LED emitters are used, in which a plurality of light emitting semiconductor chips are arranged on a common, linear substrate. These LED emitters can also be referred to as LED filaments. In the switched-on state, illuminants including such LED emitters have a similar effect to conventional incandescent lamps.

In this case, however, the individual filaments have to be mounted on a holder and subsequently joined in the desired lamp in a complex and fragile process. Moreover, it can happen that the emission characteristic of such filaments is nonuniform both with regard to the intensity and with regard to the color relative to the azimuth or polar angle of the respective filament.

### SUMMARY

In various embodiments, a light emitting component is provided. The light emitting component includes a plurality of light emitting semiconductor chips. The semiconductor chips are arranged on at least one carrier. The semiconductor chips are electrically contacted. The light emitting component further includes a converter. The converter is configured to convert light in a first wavelength range, said light being emitted by at least one portion of the light emitting semiconductor chips, at least partly into light in a second wavelength range. The converter is formed separately from the at least one carrier.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a light emitting structure in accordance with one embodiment, which is introduced into a housing of a first embodiment;

FIGS. 2A-2C show various embodiments of a housing for a chip carrier;

FIGS. 3A-3B show various embodiments of the light emitting component;

FIGS. 4A-4B show various embodiments of a carrier occupied by light emitting chips;

FIG. 5 shows a light emitting component in accordance with a further embodiment with a production method in accordance with one embodiment of the invention; and

FIGS. 6A-6E show a light emitting component in accordance with a further embodiment with an alternative production method in accordance with a further embodiment.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

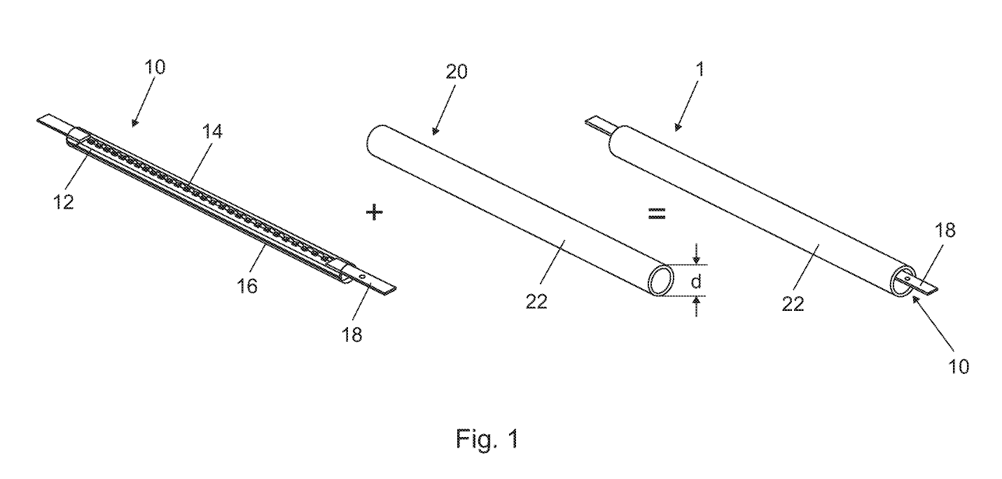

FIG. 1 shows a light emitting structure 10 in accordance with various embodiments. The light emitting structure 10 includes a carrier 12. A plurality of light emitting chips 14 are arranged on the carrier 12. The light emitting chips 14 and the carrier 12 form a unit and therefore here and hereinafter are also designated as light emitting structure 10 or as a carrier occupied by light emitting chips. The chips 14 are arranged at regular distances on the carrier 12 in FIG. 1. It goes without saying that, depending on the desired light intensity distribution or other requirements, for example the geometry, heat dissipation, and the like, the chips can also be arranged in an irregular manner. The carrier 12 is formed in a strip-shaped fashion. That means that the carrier 12 is formed such that it is significantly longer in a first transverse direction than in a second transverse direction and in a direction perpendicular to the transverse directions, which corresponds to the thickness of the carrier 12. On account of the filament-like configuration of the resulting strip-shaped component, the latter can also be referred to as a filament.

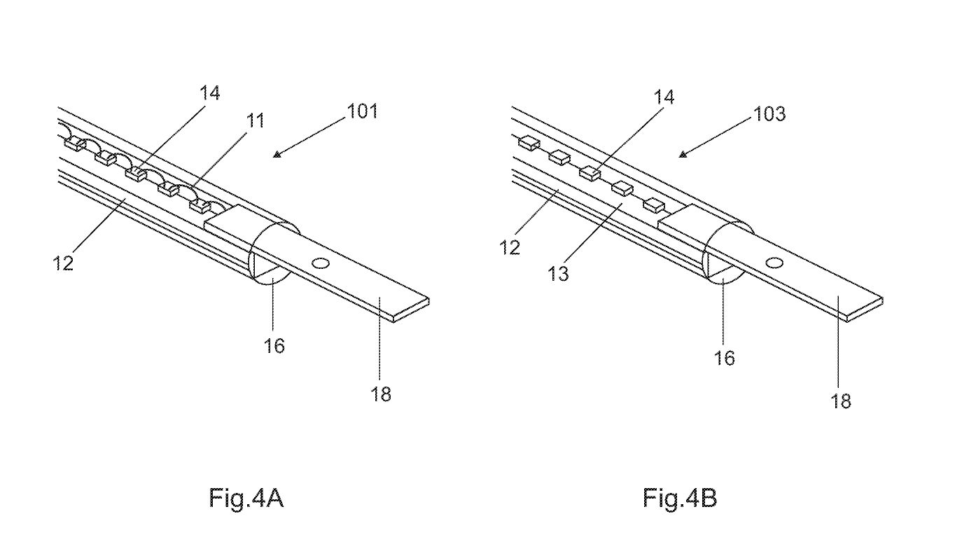

In addition, electrical contacts 18 are provided at the longitudinal sides of the carrier 12, said contacts projecting beyond the carrier 12. The electrical contacts 18 serve for electrically contacting the light emitting chips 14. The electrical contacts 18 can be secured at the end side of the carrier 12 or partly overlap the surface of the carrier 12 and be secured at the carrier 12 in the overlap region. Along the carrier 12, the chips 14 can be interconnected with one another in various ways, as will also be explained later by way of example with reference to FIGS. 4A-4B.

As is further illustrated in the embodiment in accordance with FIG. 1, the carrier 12 together with the light emitting chips 14, that is to say the light emitting structure 10, is surrounded with a protective film 16. In this case, at least one portion of the electrical contacts 18 projects from the protective film, such that the chips 14 can be contacted. The protective film 16 can serve to protect the carrier 12 occupied by light emitting chips 14 against dirt, moisture or damage. In alternative embodiments, the protective film 16 can also be omitted. In addition, the protective film 16 can have a predefined shape. In the embodiment shown according to FIG. 1, the protective film 16 is formed in a cylindrical fashion around the carrier 12. Alternatively, the protective film 16 could have a shape including a circle arc having a predefined radius and a predefined length in a peripheral region and including sections running radially with respect to a midpoint of the circle arc in a radial direction of the circle. Such a protective film would then have a circle segment shape in cross section. Consequently, by arranging a plurality of such light emitting structures 10 alongside one another in cross section a complete circle could be formed from a plurality of light emitting structures 10.

The light emitting structure 10 together with a housing 20 forms a light emitting component 1. In this case, the light emitting structure 10 is surrounded by the housing 20 in the embodiment shown according to FIG. 1 in such a way that all the light emitting chips 14 on the carrier 12 emit light through the housing 20 in a radial direction. In the embodiment in FIG. 1, the housing 20 has a cylindrical shape having a predetermined diameter d. In this case, the diameter d can be chosen in principle in accordance with the envisaged application. By way of example, the diameter d can be between 0.5 and 10 mm, e.g. between 1 and 6 mm, e.g. approximately 2 mm. In various embodiments, an upper limit for the diameter d in the context of various embodiments in this case is limited primarily by the esthetic appearance of the carrier 12 equipped with chips 14, and not on account of technical limitations. The housing 20 additionally includes a converter (e.g. a converter means 22). The converter means 22 at least partly includes a converter material suitable for converting light in a first wavelength range into light in a second wavelength range. In this case, the first and second wavelength ranges do not overlap.

It is also conceivable, moreover, for said converter means 22 to include a further converter material, which is formed and provided for converting light in the first or second wavelength range into light in a third wavelength range. Moreover, a further converter means can also be formed, which converts light in the first or second wavelength range into light in a third wavelength range.

The converter means 22 and the housing 20 can be formed integrally with one another. That is to say that the converter means 22 can be formed as part of the housing 20 or at least partly form the housing 20. In the embodiment in FIG. 1, the diameter d of the housing is chosen in such a way that the housing can receive at least one light emitting structure 10 therein. The light emitting component 1 according to various embodiments thus includes a light emitting structure 10 and a converter means 22 formed separately therefrom. Said converter means 22 and the light emitting structure 10 are combined only after an arrangement of the chips 14 on the carrier 12, such that a simplified mounting process can be carried out.

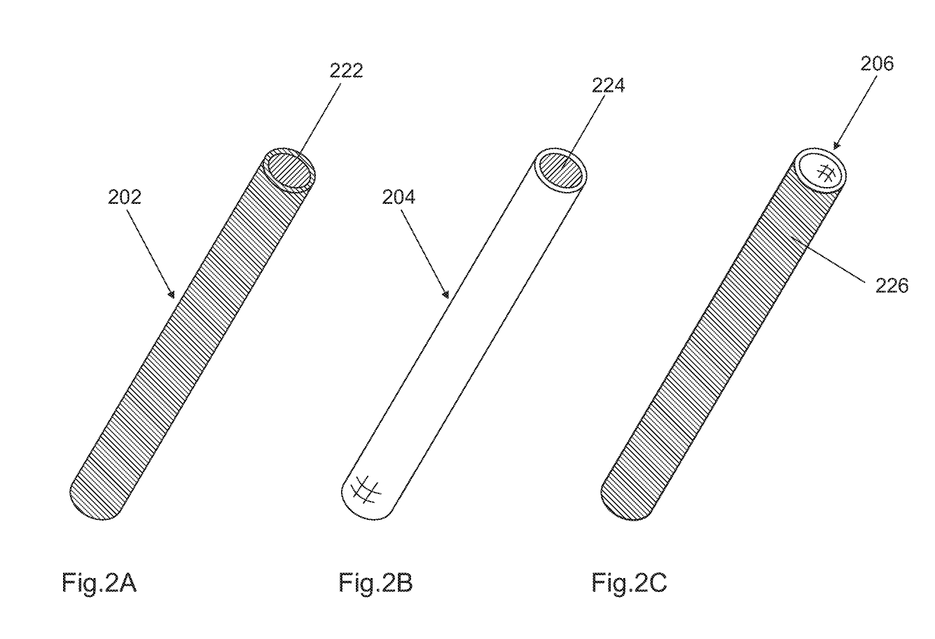

FIGS. 2A-2C illustrate various embodiments of how the housing 20 can be formed. In this regard, FIG. 2A shows an embodiment in which a converter means 222 is formed in such a way that it forms an integral part of the housing 202. The converter means 222 here has already been incorporated into the housing material or distributed, e.g. homogeneously, in the housing material. The housing 202 and the converter means 222 are therefore inseparably connected to one another. By arranging the light emitting structure 10 in the housing 202, the converter means 222 is thus simultaneously provided. In this case, it is also conceivable for the housing 202 to be formed in a hollow-walled fashion, and for the converter means 222 to be introduced into the cavity of the housing 202.

In FIG. 2B, in contrast to FIG. 2A, a converter means 224 including the converter material is provided on an inner side of a cylindrical housing 204. In this case, the inner side of the housing 204 denotes a surface of the housing 204 which faces the space enclosed by the cylinder and thus faces the light emitting structure 10 to be introduced therein. In accordance with this embodiment, the light emitted by the light emitting structure 10 passes firstly through the converter means 224 and subsequently through the housing 204. This can entail a different emission characteristic or a different absorption behavior of the housing 204 or of the entire light emitting component compared with the embodiment in accordance with FIG. 2A.

In FIG. 2C, in contrast to FIG. 2A and FIG. 2B, a converter means 226 including the converter material is formed on an outer side of a cylindrical housing 206. In this case, the outer side of the housing 206 denotes a surface of the housing 206 that faces away from the space enclosed by the cylinder and thus faces away from the light emitting structure 10 to be introduced therein. In accordance with this embodiment, the light emitted by the light emitting structure 10 passes firstly through the housing 206 and only then through the converter means 226.

In the embodiments according to FIG. 2B and FIG. 2C, the converter means 224, 226 can also be formed subsequently, that is to say after production of the housing 204, 206, on the corresponding surface of the housing 204, 206. The housing 20, 202, 204, 206 can for example consist of a glass material or include a glass material.

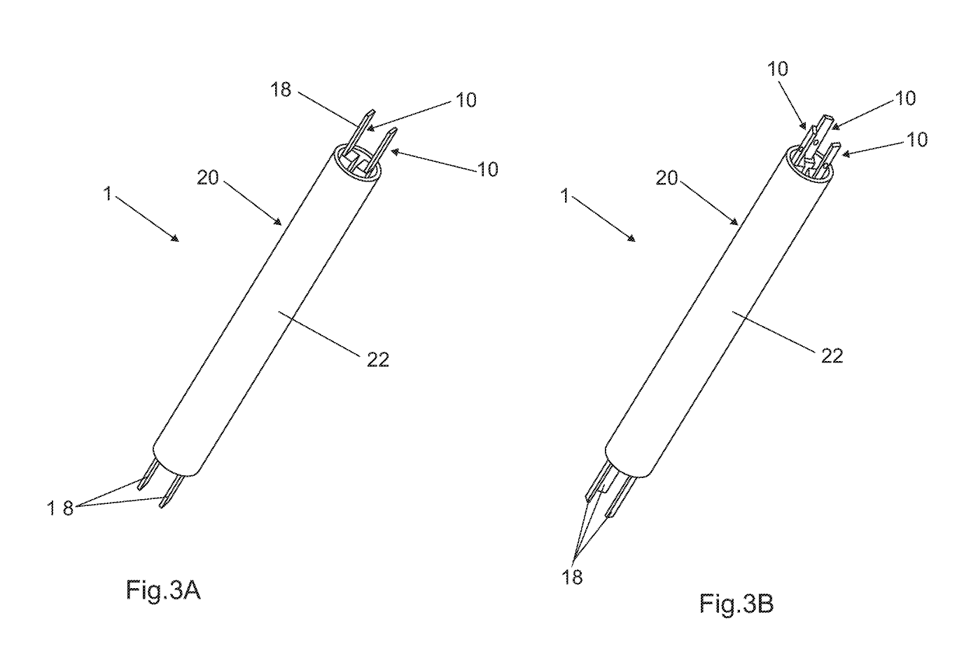

FIGS. 3A-3B show various embodiments, wherein a plurality of light emitting structures 10 are introduced into a housing 20. In this regard, in accordance with the embodiment according to FIG. 3A, two light emitting structures 10 are provided in a housing 20. FIG. 3B shows an embodiment in which three light emitting structures 10 are arranged in a housing 20.

It is conceivable for further light emitting structures 10 to be introduced into a housing 20, a receiving limit being predefined by the diameter d of the housing 20 and the dimensioning of the light emitting structures 10. In this case, the light emitting structures 10 can be connected in series or in parallel with one another. This enables a flexible adaptation of the light emitting components 1 to the available electrical power supply systems, by targeted arrangement and interconnection of the light emitting structures 10. By arranging light emitting structures 10 in housings 20 which have the same external dimensions e.g. independently of the number of light emitting structures to be received, it is possible for an outer appearance of the light emitting components to be uniform over different wattage ranges.

Moreover, it is conceivable for an additional diffuser means to be formed on, at or in the housing. Such a diffuser means can scatter the light emitted by the light emitting structure and bring about a more homogeneous emission of the light emitting component 1 in this way. In this case, the diffuser means can also be formed integrally with the converter means 22, 222, 224, 226 and/or with the housing 20, 202, 204, 206 and/or with the protective film 16.

FIGS. 4A-4B show two examples of different embodiments which a light emitting structure according to various embodiments can have. In this regard, in accordance with FIG. 4A, a plurality of light emitting chips 14 can be arranged linearly on a carrier 12 by the chips 14 being secured adhesively on the carrier. This can be achieved by the use of adhesive, for example. In this case, the carrier 12 is a passive component that serves merely for mechanically stabilizing and for carrying the chips 14.

In the example in FIG. 4A, the chips 14 are connected to one another and to the electrical contacts 18 in series by means of a wiring 11 and together with the carrier form a light emitting structure 101. In this case, the carrier 12 can be a sapphire carrier, for example.

In the example in FIG. 4B, a connection layer 13 is formed on the carrier 12. In this case, the chips 14 are connected to the connection layer 13. In this case, the connection of the chips 14 to the connection layer 13 may e.g. also be a conductive connection which, besides a fixing of the chips 14, also produces an electrical contacting of the chips 14 on the connection layer 13 and thus on the carrier 12. This can be effected for example by soldering the chips onto the connection layer 13. Consequently, the chips 14 together with the connection layer 13 and the carrier 12 form a light emitting structure 103. The connection layer 13 can be a printed circuit board, for example. Moreover, the carrier in accordance with this embodiment can be a sapphire substrate formed with metalizations that serve for contacting the chips.

In addition, it is conceivable for the carrier to include or consist of sapphire, glass and/or semitransparent or highly reflective ceramics such as Al2O3, for example.

Moreover, in some embodiments, the chips 14 can be arranged on the carrier 12 or the connection layer 13 not only in a single-row, linear arrangement but also in a plurality of rows or irregularly. The distribution of the chips 14 on the carrier or the connection layer can be effected for example depending on an emission characteristic to be achieved.

It is additionally possible that, in a method process after the light emitting structure 10 has been introduced into the housing 20, 202, 204, 206, a filling material, which can also contain the diffuser means, for example, is introduced into the space enclosed by the housing. In this way, the one or the plurality of light emitting structures can be held or fixed in the housing 20, 202, 204, 206.

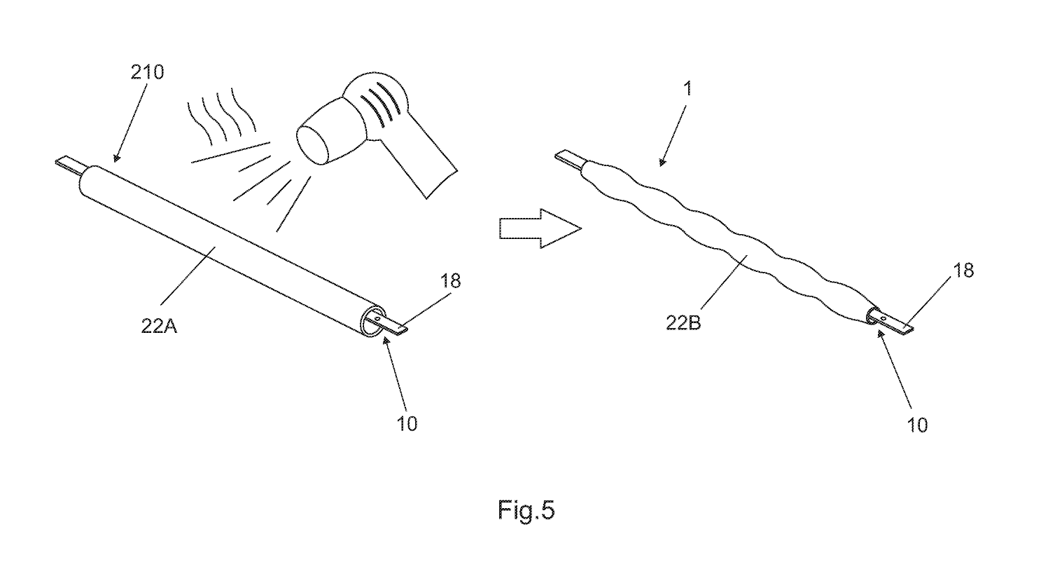

FIG. 5 shows an alternative method for providing a housing 210 around a light emitting structure 10. In this case, the housing 210 includes a material that shrinks when heat is supplied. In various embodiments, the material of the housing 210 shrinks irreversibly, such that the housing 210 settles around the light emitting structure 10, e.g. without any gaps, on account of the supply of heat. As a result of the supply of heat, as illustrated in FIG. 5, e.g. a converter means 22A can be formed integrally with the housing 210. As a result of the supply of heat, therefore, the converter means 22A also contracts to form a converter means 22B arranged around the light emitting structure without any gaps.

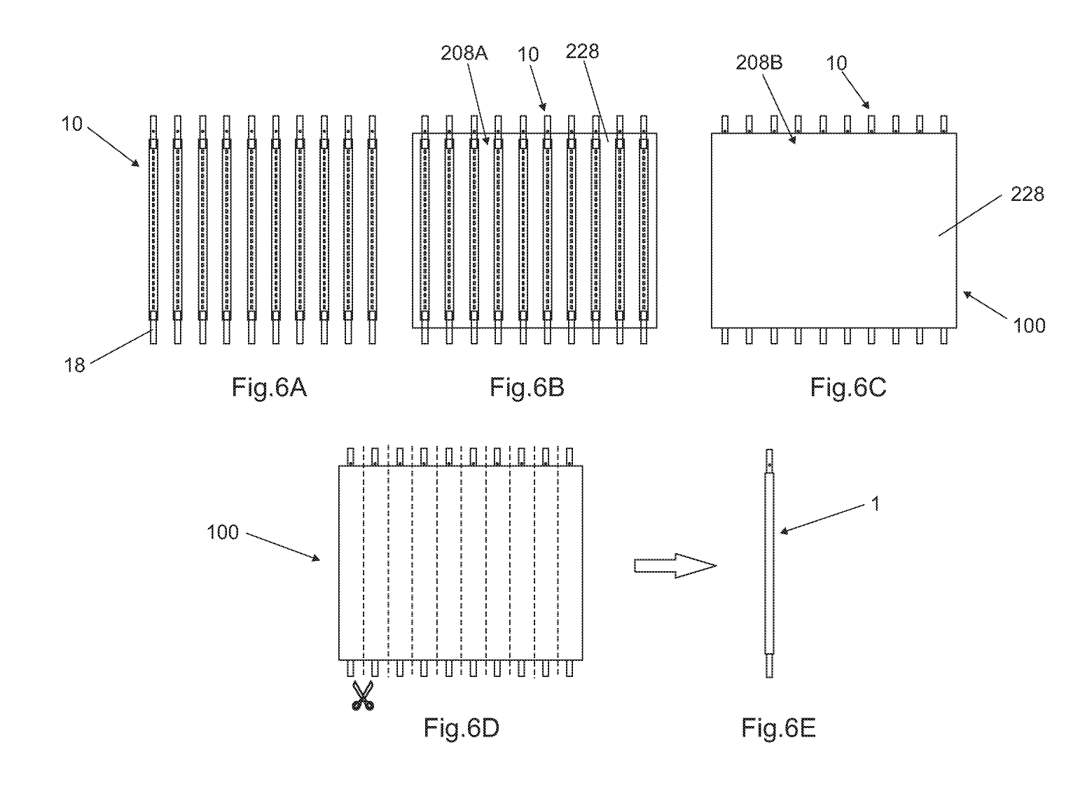

FIGS. 6A-6E show a further alternative method according to various embodiments. One aspect consists in forming the light emitting structure in such a way without in this case providing a converter means during the production process on the individual chips. According to various embodiments, a converter means is then formed in a subsequent step above or around a carrier 12 equipped with light emitting chips 14, at least for a portion of the carrier equipped with light emitting chips 14. The embodiment of a method for providing a light emitting component 1 as illustrated in FIGS. 6A-6E differ from the embodiments explained above in that, instead of a rigid housing, provision is made of one or more films with a converter means above a plurality of light emitting structures 10.

In a first process, cf. FIG. 6A and FIG. 6B, a plurality of light emitting structures 10, that is to say carriers 12 equipped with light emitting chips 14, are arranged alongside one another, e.g. parallel to one another, on a film 208 A including the converter means 228. In this case, the carriers 12 equipped with chips 14 are covered by the film, but the electrical contacts 18 situated at the end sections of the carriers 12 are not covered by the film. In this case, the film 208 A is formed with an adhesive material and/or with a heat activatable adhesion material on a surface facing the light emitting structure. In a next process, as illustrated in FIG. 6C, a second film 208 B is arranged above the light emitting structures 10 situated on the first film 208 A, said second film e.g. extending congruently with respect to the first film 208 A. It is also conceivable for the second film 208 B to be formed integrally with the first film 208 A, and to be arranged on the light emitting structures 10 by folding over a projection of the first film 208 A. A matrix 100 composed of light emitting structures 10 arranged alongside one another and equipped with converter film 208 A, 208 B is created as a result. In this case, the converter film 208 A, 208 B serves both as converter means and as housing.

In a next process, the matrix 100, as necessary, preferably carrier by carrier, can be singulated or provided with a predetermined breaking location or a perforation in the matrix 100. In a final process, which can be performed during production or after production, before use, singulation by separating the perforation can then in turn be carried out.

Various embodiments may improve at least one of the disadvantages mentioned. In various embodiments, a light emitting component is provided which can be produced in a simplified manner. Moreover, various embodiments provide a method for manufacturing a component in a simplified manner.

A first aspect relates to a light emitting component including a plurality of light emitting semiconductor chips. In this case, the semiconductor chips are arranged on at least one carrier and electrically contacted. Moreover, the light emitting component includes a converter means, wherein the converter means is configured to convert light in a first wavelength range, said light being emitted by at least one portion of the light emitting semiconductor chips, at least partly into light in a second wavelength range. In this case, the converter means is formed separately from the at least one carrier. In various embodiments, the first wavelength range and the second wavelength range do not overlap.

In various embodiments, the conversion means only partly converts the radiation of the LED chips, such that a certain proportion of the radiation of the LED chips passes through the conversion means without being converted. In this way, the light emitting component emits mixed-colored radiation composed of converted and unconverted radiation. In various embodiments, the light emitting component emits mixed-colored radiation having a color locus in the white region of the CIE standard chromaticity diagram.

As a result of the converter means being provided separately from the carrier equipped with semiconductor chips, it is possible to skip a step of applying the converter material during the production of the individual semiconductor chips. This can simplify the production process by virtue of the fact that the converter means can be implemented jointly for all the semiconductor chips after the semiconductor chips have been positioned on a carrier. Moreover, the appearance of a traditional incandescent filament can be better imitated by providing the converter means, for example in the form of a common encapsulation around a semiconductor chip carrier.

The semiconductor chips can be formed in particular as LED chips. The LED chips typically include an epitaxially grown semiconductor layer sequence having an active zone, which generates electromagnetic radiation in a first wavelength range during operation. The electromagnetic radiation generated during the operation of an LED chip is emitted by the LED chip from a primary light exit surface that runs parallel to the semiconductor layers and forms a surface of the semiconductor chip.

The LED chips can be so-called volume emitters, for example. A volume emitting LED chip includes a substrate, on which the semiconductor layer sequence was generally grown epitaxially. The substrate may include or consist of sapphire or silicon carbide, for example. In principle, the substrate can at least include all III/V and II/VI compound semiconductors. In addition, silicon or germanium, for example, is also conceivable. Volume emitting LED chips generally emit the radiation generated in the active zone not just via the primary light exit surface, but also via their side surfaces.

Furthermore, the LED chips can also be thin-film LED chips. Thin-film LED chips include an epitaxially grown semiconductor layer sequence applied on a different carrier than the growth substrate for the semiconductor layer sequence. A mirror layer can be arranged between the semiconductor layer sequence and the carrier, said mirror layer directing radiation of the active zone to the light exit surface. Thin-film LED chips generally do not emit the electromagnetic radiation generated in the active zone during operation via the side surfaces of the carrier, but rather have a substantially Lambertian emission characteristic.

In accordance with one embodiment of the LED filament, a plurality of LED chips are used, which are electrically interconnected with one another in a row in series and/or in parallel. The LED chips can be electrically contacted by means of bond wires, tapes or else lithographically. By way of example, the LED chips can be electrically interconnected with one another in series by means of front-side bond wires.

It is conceivable, moreover, for the LED filament to consist of one or more component parts each including a plurality of light emitting regions. In this case, a substrate may include a plurality of light emitting sections. Such light emitting sections on the substrate can be created for example by the light emitting semiconductor layers being applied on a substrate by means of the known methods. Afterwards, the sections can be produced by structuring the semiconductor layer. In addition, it is likewise conceivable for the light emitting sections to be produced already during the process of growing the semiconductor layer sequence.

The converter means can be formed around the entire emissive surface of the carrier. A greater homogeneity of the emitted and subsequently converted light can be achieved in this way. By virtue of the fact that the light emitted by the semiconductor chips has to cover the same path distance through the separately formed converter means in a radial direction proceeding from the respective chip, the emission of the light and the color temperature thereof can thus be more homogeneous in said radial direction. In various embodiments, a more homogeneous wavelength conversion can take place in all directions in this way.

It is also conceivable in some embodiments of the invention for the converter means to have an inhomogeneous shape, for example an inhomogeneous thickness, or for the converter material to have a predefined distribution in the converter means. In this case, the converter material can be distributed homogeneously but also inhomogeneously in and/or on the converter means. An inhomogeneous emission of light from the respective chips in different spatial directions can be compensated for to the effect that a color temperature, that is to say a conversion proportion of light, is provided approximately identically in all directions proceeding from the individual chip.

In various embodiments, it is conceivable for the converter material to be distributed inhomogeneously in the converter means in such a way that a physical treatment of the converter means, for example by heating or folding, leads to a predefined, e.g. homogeneous, distribution of the converter material when the converter means has the envisaged arrangement around the LED emitter.

In some embodiments, the converter means is formed as a housing. In this case, the housing is dimensioned in such a way that it is suitable for receiving at least one carrier equipped with light emitting semiconductor chips. The carrier can be e.g. a strip-shaped carrier, as is the case for example for a filament-like component. In this case, in some embodiments the housing can be formed as a dimensionally stable component. In this case, in the context of the present invention, dimensionally stable should be understood to mean any material which, on the one hand, can maintain an outer shape by virtue of inherent material properties of the housing. That may also include materials which have a solid or for example liquid or flowable or deformable state depending on the temperature. On the other hand, the housing material must simultaneously be at least partly transmissive to the emitted wavelength ranges of the semiconductor chips. In this way, a carrier equipped with semiconductor chips can be received in the housing and emit light into or through the housing. In this way, the carrier can be protected by the housing. This can reduce the risk of damage to the carrier and/or the semiconductor chips or contamination. Moreover, mounting or receiving of the carrier in the housing can be simplified e.g. by means of a dimensionally stable housing material.

In various embodiments, housings having the same dimensions can be used for different carriers and/or illuminants. In this way, an external appearance of different light emitting components can be identical, independently of the chips or LEDs used.

In various embodiments, the housing can be formed as a cylindrical housing, e.g. having end-side openings which enable access to the interior enclosed by the housing. In the case of such a cylindrical housing, at least one LED emitter, that is to say a carrier occupied by semiconductor chips, can be introduced into the interior of the cylindrical housing. In this case, the receiving may be effected in such a way that the entire carrier with the exception of its two longitudinal end sections is received in the housing. In such embodiments, the terminal contacts for contacting the semiconductor chips arranged on the carrier are e.g. in the region of the two longitudinal end sections of the carrier. In some embodiments, it is also conceivable for contacting to be provided only at one end of the carrier. In these embodiments, it is also conceivable for the housing to have an opening to the interior enclosed thereby only at one end side.

The housing can also be dimensioned in such a way that more than one LED emitter, e.g. two or three LED emitters, can be received in the interior enclosed by the housing. This can make it possible to improve a homogeneity of the emission from the entire component with regard to color temperature and intensity. Moreover, in this way a forward voltage of the component can be adapted to a power supply system voltage in a simplified manner. In this regard, a forward voltage of an LED emitter can be set to approximately 85 V-90 V by corresponding arrangement and wiring of the semiconductor chips on the carrier. Given a power supply system voltage of 230 V, by way of example, two of the LED emitters according to various embodiments may then be connected in series, while the same two LED emitters can be connected in parallel given a power supply system voltage of 110 V. In various embodiments, in this case, light emitting components according to various embodiments are combined in such a way that in total a number of LED emitters which are interconnected in a lamp corresponds to a multiple of two. These are then combined and interconnected with one another in accordance with the power supply system voltage. Moreover, applications for other voltage ranges, such as 12 V, for example, are also conceivable by corresponding alteration of the number and the arrangement of the chips on a filament-like component.

In some embodiments, at least one surface of the converter means includes a converter material suitable for conversion from the first wavelength range to the second wavelength range. That means that a converter material is provided on at least a top side of the converter means. In the case of a cylindrical converter means, for example, this can involve an inner surface of the converter means, that is to say a side of the converter means facing the carrier or carriers. In addition, it is also conceivable for the converter material to be provided on an outer surface of the converter means, that is to say a side of the converter means facing away from the carrier or carriers. In this regard, a process of arranging the converter material on the converter means can be effected after production of the housing and need not already be performed during the production process. This can simplify an adaptation of the converter means to the carriers used. The converter means can thus be produced separately from the light emitting component.

It is also conceivable for the converter means to be formed in a hollow-walled fashion and for a cavity to be at least partly filled with the converter material. In this case, the filling can be homogeneous or inhomogeneous. Additionally or alternatively, the housing may include a material or consist of a material which is mixed and/or interspersed, in particular homogeneously, with the converter material. Integral combination of the housing with the converter means or converter material can allow simplified mounting.

As already explained, the converter means includes at least one converter material which converts light from a first wavelength range into light from a second wavelength range. It is also conceivable for a further converter material to be provided in, on or separately from the converter means, which converts light from the first and/or from the second wavelength range into light from a third wavelength range. In this case, the wavelength ranges can be separate from one another or else, at least partly, overlap one another. A color locus of the emitted light can be set in this way. The second converter material can be formed e.g. on a surface or, similarly to the first converter material, in the converter means or a housing. In this case, provision can also be made of a further converter means, separately from the converter means mentioned, which includes the second converter material. In this case, the second converter means can be formed and arranged in a similar manner to that already explained for the converter means.

The second converter material can in turn be arranged and formed homogeneously or inhomogeneously, in a manner as already explained for the first converter material.

In some embodiments, the converter means may include a glass material. In this case, the converter means can also completely consist of the glass material. In principle, the converter material is transparent or at least partly transparent in a predetermined wavelength range e.g. in the visible range of the electromagnetic spectrum.

In addition, in some embodiments, the converter means can also include or consist of a shrinkable material, in particular a heat shrinkable material. This can enable facilitated mounting of the light emitting component in the converter means. In addition, this can enable protection of the light emitting elements, for example against moisture or contamination. The heat shrinkable material may include or consist of, for example, polyolefins, polyvinylidene fluoride (PVDF), polyvinyl chloride (PVC) and/or polytetrafluoroethene (PTFE) or Teflon. These materials can either be filled or intermixed with particles for wavelength conversion or else be produced in a transparent fashion.

In further embodiments, the converter means includes a film including the phosphor or the phosphors. In this case, the film is arranged around at least one portion of the light emitting semiconductor chips. In this way, a simple formation of the converter means around the light emitting structure can be effected, which can enable a simplified and accelerated production process. In this case, the film can be for example a self-adhesive film, a heat activatable film, which acquires adhesive properties when heat is supplied, or other suitable films. The film can also be secured on the light emitting structure by separate adhesion means, for example by supplying an adhesive layer before the complete enclosure of the light emitting structure.

In further embodiments, it is conceivable, moreover, for the light emitting component to include a diffuser material. The diffuser material can be formed on the converter means and/or in the converter means and/or between the converter means and the at least one carrier. The diffuser material can contribute to the light emitting element having a more homogeneous emission. The diffuser material, if it is formed between the carrier and the converter means, can also contribute to the converter means being illuminated more uniformly by the emitted light. In this way, an evolution of heat in the converter on account of the conversion process can also be distributed more homogeneously in the converter means.

The converter means is advantageously formed for receiving a plurality of carriers equipped with semiconductor chips, or more generally a plurality of light emitting structures. In various embodiments, the converter means can be formed for receiving two or three carriers. In this way, an interconnection and wiring of the light emitting semiconductor chips can already be carried out before final mounting in the converter means and the wired carriers and light emitting semiconductor chips can be arranged jointly in the converter means.

In some embodiments of the light emitting components, the light emitting chips are electrically interconnected with one another in series and/or in parallel. The light emitting chips can be electrically contacted by means of bond wires, tapes or else lithographically. By way of example, the LED chips are electrically interconnected with one another in series by means of front-side bond wires.

The carrier element of the light emitting component may include a first electrical contact location on a first end region of the first main surface. By way of example, the front side of the directly adjacent LED chip can be electrically conductively connected to the contact location by a bond wire. In this case, the first contact location may e.g. be electrically insulated from the carrier element.

It is additionally possible for the LED chips or the carriers having the light emitting chips to be embedded into a protective layer that is free of wavelength-converting properties and serves merely for the protection of the LED chips and/or the mechanical stabilization of the light emitting structure. This can simplify production of LED components according to various embodiments.

The carrier equipped with semiconductor chips may include a sapphire carrier. In this case, the semiconductor chips can preferably be adhesively bonded on the carrier and contacted with one another by means of wire connection.

Alternatively, the carrier equipped with semiconductor chips may include a sapphire substrate, wherein the sapphire substrate e.g. includes metalizations for connecting the semiconductor chips and the semiconductor chips are e.g. secured and contacted on the carrier by means of a solder.

Once again as an alternative, the semiconductor chips can be arranged as light emitting sections on a substrate or auxiliary carrier.

A method according to various embodiments for producing a light emitting component in accordance with one embodiment includes a process according to which a carrier equipped with a plurality of light emitting semiconductor chips is provided. In addition, a converter means is provided, for converting light emitted by at least one portion of the semiconductor chips. The carrier equipped with the semiconductor chips and the converter means are arranged in such a way that the converter means surrounds the carrier and/or the carrier is received in the converter means.

In this context, “surround” means that the converter means projects beyond or overlaps the carrier at least partly in a radial direction proceeding from the carrier directly, that is to say in direct contact, or only indirectly, if appropriate also with intervening layers.

The semiconductor chips can be arranged at regular or irregular distances on the carrier.

In one development of the method, the converter means is a glass cylinder, into which at least one carrier equipped with semiconductor chips is introduced.

Alternatively, the converter means may include a heat shrinkable material. In this case, at least one carrier equipped with semiconductor chips is surrounded by the heat shrinkable converter material. The heat shrinkable converter material is subsequently heated. The heating may be effected in such a way that the heat shrinkable converter material shrinks and contracts, such that it closes, e.g. without any gaps, around the carrier and the light emitting chips arranged thereon. In addition, it is possible to use for this purpose materials which are deformable by sufficient heating and in this way adapt to the contour of the carrier with chips mounted thereon. In various embodiments, the heat shrinkable material can be a material which permanently contracts as a result of the heat treatment.

In once again an alternative method, the converter means is formed as a film including a converter material. In this case, at least one carrier is arranged by a first surface on the converter material and a second surface of the carrier is then covered with the converter material.

A plurality of carriers can also be arranged on the film including the converter material. In this case, all the carriers are covered with the film, e.g. with the same film. After the encapsulation of the plurality of carriers, the carriers encapsulated with the film are then finally singulated.

In this case, both such a film and such a heat shrinkable material may e.g. be formed in such a way that the converter material is embedded into the film material and respectively into the heat shrinkable material. Other embodiments are also possible, of course, as mentioned in the context of the converter means.

By way of example, one of the following materials is suitable for the phosphor particles or the converter particles, the enumeration not being exhaustive, but rather only of exemplary nature: garnets doped with rare earths, alkaline earth metal sulfides doped with rare earths, thiogallates doped with rare earths, aluminates doped with rare earths, silicates doped with rare earths, orthosilicates doped with rare earths, chlorosilicates doped with rare earths, alkaline earth metal silicon nitrides doped with rare earths, oxynitrides doped with rare earths, aluminum oxynitrides doped with rare earths, silicon nitrides doped with rare earths, sialons doped with rare earths. Further phosphors known to the person skilled in the art are likewise conceivable.

### LIST OF REFERENCE SIGNS

1 Light emitting component
10, 101, 103 Light emitting structure
11 Wiring
12 Carrier
13 Connection layer
14 Light emitting chip
16 Protective film
18 Electrical contact
208 A, 208 B Converter film
100 Matrix composed of light emitting structures
20, 202, 204, 206, 208, 210 Housing
22, 22A, 22B, 222, 224, 226, 228 Converter means

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A light emitting component, comprising:
a plurality of light emitting semiconductor chips, wherein the semiconductor chips are arranged on at least one carrier, and wherein the semiconductor chips are electrically contacted;
a converter, wherein the converter is configured to convert light in a first wavelength range, said light being emitted by at least one portion of the light emitting semiconductor chips, at least partly into light in a second wavelength range, and wherein the converter is formed separately from the at least one carrier.

2. The light emitting component of claim 1,
wherein the converter is formed as a housing configured to receive at least one carrier equipped with light emitting semiconductor chips.

3. The light emitting component of claim 1,
wherein the converter is formed in a cylindrical fashion.

4. The light emitting component of claim 1,
wherein at least one surface of the converter comprises a converter material suitable for conversion from the first wavelength range to the second wavelength range.

5. The light emitting component of claim 4,
wherein the converter material is formed on a surface of the converter facing the carrier.

6. The light emitting component of claim 4,
wherein the converter material is formed on a surface of the converter facing away from the carrier.

7. The light emitting component of claim 4,
wherein at least one of the converter is formed in a hollow-walled fashion and a cavity is at least partly filled with the converter material, or the converter comprises a material or essentially consists of a material which is at least one of mixed or interspersed with the converter material.

8. The light emitting component of claim 1,
wherein a second converter material is provided, which is suitable for converting the emitted or converted radiation from at least one of the first wavelength or the second wavelength to a third wavelength.

9. The light emitting component of claim 8,
wherein the second converter material is formed on a surface of the converter.

10. The light emitting component of claim 1,
wherein the converter comprises a glass material.

11. The light emitting component of claim 1,
wherein the converter comprises a heat shrinkable material.

12. The light emitting component of claim 1,
wherein the converter comprises a film which comprises a phosphor or phosphors and which is arranged around at least one portion of the light emitting semiconductor chips.

13. The light emitting component of claim 1,
wherein the light emitting component comprises a diffuser material formed at least one of on the converter or in the converter or between the converter and the at least one carrier.

14. The light emitting component of claim 1,
wherein the converter is formed for receiving a plurality of carriers equipped with semiconductor chips.

15. The light emitting component of claim 1,
wherein the carrier equipped with semiconductor chips comprises a sapphire carrier.

16. The light emitting component of claim 1,
wherein the carrier equipped with semiconductor chips comprises a sapphire substrate.

17. A method for manufacturing a light emitting component, the method comprising:
providing a carrier equipped with a plurality of light emitting semiconductor chips;
providing a converter for converting light emitted by at least one portion of the semiconductor chips;
wherein at least one of the carrier equipped with the semiconductor chips and the converter are arranged in such a way that the converter surrounds the carrier or the carrier is received in the converter.

18. The method of claim 17,
wherein the converter is a glass cylinder, into which at least one carrier equipped with semiconductor chips is introduced.

19. The method of claim 17,
wherein the converter comprises a heat shrinkable material:
wherein at least one carrier equipped with semiconductor chips is surrounded by the heat shrinkable converter and the heat shrinkable material is subsequently heated in such a way that the heat shrinkable material closes around the carrier.

20. The method of claim 17,
wherein the converter is formed as a film comprising a converter material and at least one carrier is arranged by a first surface on the converter material and a second surface of the carrier is covered with the converter material.

21. The method of claim 20,
wherein a plurality of carriers are arranged on the film comprising the converter material and are covered with the film;
wherein, after the process of encapsulating the plurality of carriers, the carriers are singulated.
